(19) United States
(12) Patent Application Publication
(10) Pub. No.: US 2015/0364899 A1
(43) Pub. Date: Dec. 17, 2015

(54) BRAGG GRATING EXTERNAL CAVITY LASER

(71) Applicant: Seagate Technology LLC, Cupertino, CA (US)

(72) Inventors: Karim Tatah, Eden Prairie, MN (US); Pierre Asselin, Richfield, MN (US)

(21) Appl. No.: 14/619,745

(22) Filed: Feb. 11, 2015

Related U.S. Application Data
(60) Provisional application No. 62/011,243, filed on Jun. 12, 2014.

(51) Int. Cl. H01S 5/14; H01S 3/08; H01S 5/028

(52) U.S. Cl. CPC H01S 5/141; H01S 5/028; H01S 3/08009

(57) ABSTRACT

A Bragg grating external cavity laser apparatus may comprise the combination of a slider and an external cavity laser. The slider includes a waveguide that delivers light to a recording media. The external cavity laser includes an active region with a reflective back facet and a front facet that is externally coupled to the waveguide of the slider. The external cavity laser additionally includes a Bragg grating within the waveguide of the slider where the reflective back facet and the Bragg grating operate to define a single resonator within the external cavity.

### RELATED PATENT DOCUMENTS

This application claims the benefit of Provisional Patent Application Ser. No. 62/011,243 filed on Jun. 12, 2014, to which priority is claimed pursuant to 35 U.S.C. §119(e), and which is incorporated herein by reference in its entirety.

### SUMMARY

A Bragg grating external cavity laser apparatus may comprise the combination of a slider and an external cavity laser. The slider includes a waveguide that delivers light to a recording media. The external cavity laser includes an active region with a reflective back facet and a front facet that is externally coupled to the waveguide of the slider. The external cavity laser additionally includes a Bragg grating within the waveguide of the slider where the reflective back facet and the Bragg grating operate to define a single resonator within the external cavity.

A Bragg grating external cavity laser apparatus may comprise the combination of a slider and an external cavity laser. The slider includes a waveguide that delivers light to a recording media. The external cavity laser includes an active region with a reflective back facet and a front facet that is externally coupled to the waveguide of the slider. The external cavity laser additionally includes a Bragg grating within the waveguide of the slider where the reflective back facet and the Bragg grating operate to define a single resonator within the external cavity. The Bragg grating is tuned to enable a selected light wavelength to pass through the Bragg grating and to reflect all other light wavelengths into the internal cavity.

A Bragg grating external cavity laser method may comprise generating a beam of light, anti-reflectively coupling the light into a slider waveguide, transmitting selected wavelengths of the coupled light through the waveguide and reflecting other wavelengths of the coupled light to establish a single longitudinal mode in the waveguide.

The above summary is not intended to describe each embodiment or every implementation. A more complete understanding will become apparent and appreciated by referring to the following detailed description and claims in conjunction with the accompanying drawings.

### BRIEF DESCRIPTION OF THE DRAWINGS

FIG. 1 is a schematic representation of a portion of a slider coupled to a laser diode.

FIG. 2 is a schematic representation of a portion of a slider coupled to a laser diode in accordance with various embodiments described herein.

FIG. 3 is a cross-section taken along line 3-3 of FIG. 2.

FIG. 4 is a graph depicting Bragg mirror reflectivity with varying peak reflectivity and spectral width.

FIGS. 5-7 illustrate example embodiments of the waveguide of a slider incorporating a Bragg grating in accordance with various embodiments described herein.

FIG. 8 is a flowchart of a method according to an example embodiment.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

Heat assisted magnetic recording (HAMR) generally refers to the concept of locally heating a recording media to reduce the coercivity of the media so that an applied magnetic writing field can more easily direct the magnetization of the media during the temporary magnetic softening of the media caused by the heat source. The heated area in the storage layer usually determines the data bit dimension. A tightly confined, high power light spot is used to heat a portion of the recording media to substantially reduce the coercivity of the heated portion. Then the heated portion is subjected to a magnetic field that sets the direction of magnetization of the heated portion. In this manner the coercivity of the media at ambient temperature can be much higher than the coercivity during recording, thereby enabling stability of the recorded bits at much higher storage densities and with much smaller bit cells.

The recording media may be heated using a light beam generated by a laser diode and coupled into the recording head. Because the waveguide structure inside the laser diode is quite different from the guiding structure inside the recording head, challenges exist in establishing a desirable design fir coupling the output of the laser diode to the recording head. One particular problem to note is the power instabilities, or jumps, experienced by the laser diode whenever there is external optical feedback to the laser. The power jumps can be as high as 25%. The power jumps may cause jitter instability in heat assisted magnetic recording which has a direct impact on the signal-to-noise ratio, areal density, and bit error rate in the recording process.

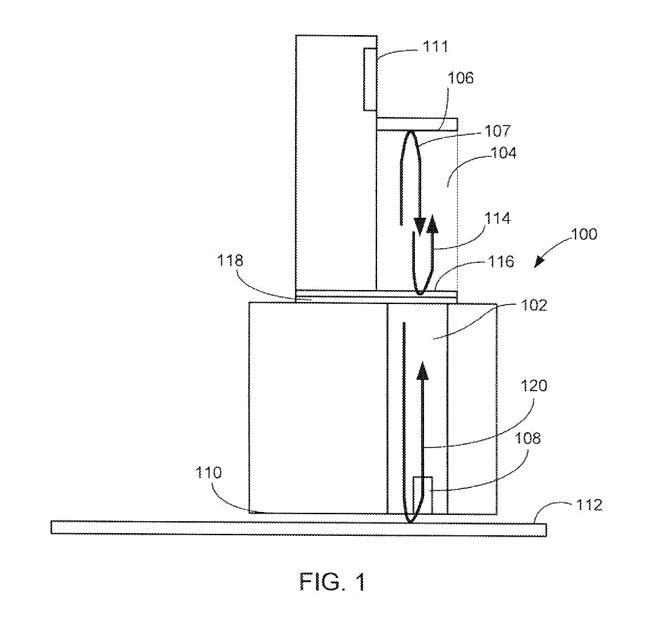

FIG. 1 is a schematic representation of a portion of a slider 100, also known as a recording head, which illustrates the locations of problematic optical feedback. The slider 100 includes a waveguide 102 that is coupled to a laser diode portion 104, having a reflecting back facet 106 (reflecting light indicated by arrow 107), to provide light energy to near field transducer (NFT) 108 at the air bearing surface (ABS) 110. A detector 111 resides proximate laser diode portion 104 while a magnetic storage medium 112 is positioned proximate the ABS 110. Arrow 114 indicates optical feedback that occurs between the front laser facet 116 and the optical coupler 118 interface. Arrow 120 indicates additional optical feedback that occurs at the ABS 110—magnetic storage medium 112 interface. This optical feedback introduces mode selectivity between the internal laser resonator and the external resonator, which includes the front laser facet 116 and the external reflector (magnetic storage medium 112), Mode competition among these resonators induced by laser gain shift with injected current and self heat leads to power jump instabilities

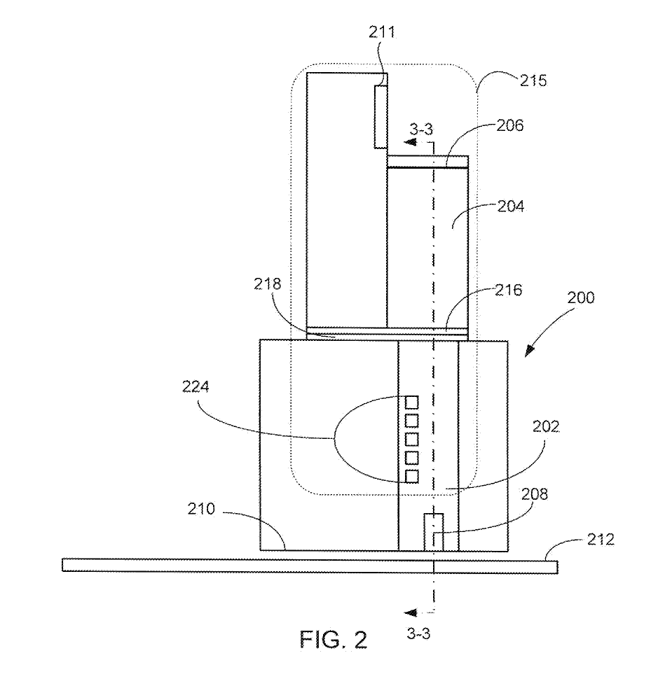

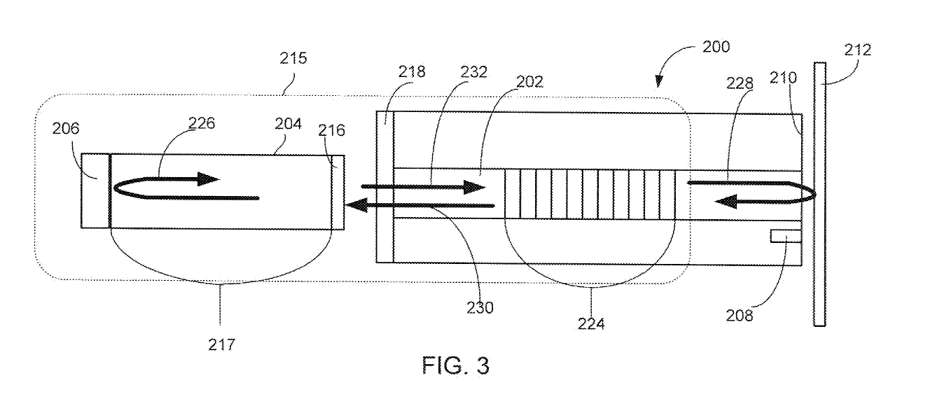

The present disclosure provides a laser cavity design that substantially avoids multiple cavity mode competitions and mode hopping power instabilities by utilizing a single distributed Bragg grating (DBR) external cavity. More specifically, the present disclosure is directed to an external cavity laser that combines the laser gain medium to an external cavity formed using a Bragg grating, built in the integrated optic space of the slider, and the back facet of the laser diode. An example embodiment of an apparatus of the present disclosure is illustrated in FIG. 2, Here a slider 200 includes a waveguide 202 that is coupled to a laser diode portion 204, having a. reflecting back facet 206, to provide light energy to a near field transducer (NFT) 208 at an air bearing surface (ABS) 210. A detector 211 resides proximate laser diode 204 while a magnetic storage medium 212 is positioned proximate the ABS 210. Further included within the waveguide 202 of the slider is a Bragg grating 214. The Bragg grating 214 forms a resonator together with the reflecting back facet, and together they form an external cavity laser 215. A cross-section of FIG. 2 is provided in FIG. 3 and lustrates further detail of the embodiment.

As shown in FIG. 3, the laser diode portion 204 includes the reflecting back facet 206, which in one embodiment provides approximately 95% reflection of the laser diode energy. The laser diode portion 204 further includes a laser front facet 216, which is coated in an anti-reflective coating, and a laser active region 217, which has a length in the approximate range of 350 to 500 μm. The slider 200 includes a slider coupler 218 that is additionally coated with an anti-reflective coating such that the interface between the laser front facet 216 and the slider coupler 218 has a reflectivity of less than 0.2 to 1.0%. A Bragg grating 224, having a length in the approximate range of 200 to 500 μm, is provided within the waveguide 202. The Bragg grating 224 forms the output coupler of the external cavity laser 215 that is established by the single resonator formation of the laser back facet reflector 216 and the Bragg grating 224. Light reflection points are indicated with returning arrows 226 and 228 while straight arrows 230 and 232 indicate the transmission of light to and from the Bragg grating 224.

The Bragg grating 224, also known as a distributed Bragg reflector (DBR), allows light of a certain wavelength from the laser diode 204 to pass through the waveguide 202 to the magnetic storage medium 212 while all other light wavelengths are reflected back from the Bragg grating 224 into the laser cavity. Approximately 50% of the light energy reaching the magnetic storage medium 212 may be reflected by the magnetic storage medium 212 back into the waveguide 202; however, the medium-reflected light is essentially stopped by the Bragg grating 224 preventing it from reaching the laser cavity. Some losses do occur within the waveguide 202 due to material imperfections and/or imperfect alignment of optical components and, as such some medium-reflected light does reach the laser diode 204; this reflection is generally estimated as in the 7 to 10% range.

Note that the gain for a given current injection to the laser diode 204 needs to overcome any loss in the external cavity for lasing to occur. Once the current bias level is reached for the gain to compensate for any loss the laser diode 204 will provide sufficient power for the NFT to drive the magnetic storage medium 212 to the Curie temperature needed in heat assisted magnetic recording. The laser threshold of the presently disclosed external cavity, Bragg grating laser is substantially equivalent, or at most 10% higher, than the laser diode without an external cavity as described in relation to FIG. 1. This is because the overall light intensity returning to the external cavity laser is on the order of 5 to 20% equivalent to the laser of FIG. 1 with 5 to 15% return for the front facet of the laser.

The Bragg grating may be designed specific to the slider in which it resides. For example, the Bragg grating may reside in the waveguide or the cladding of the waveguide, the Bragg grating may be tuned to allow a desired wavelength of light to pass, and/or the grating strength may be adjusted to achieve desired peak reflectivity. A non-limiting example of distributed Bragg grating (DBR) design is provided below for reference.

### EXAMPLE

A reasonable performing external cavity DBR (EC-DBR) laser includes a rear facet with 95% reflection and effective front facet reflectivity of 5 to 15%. The front facet effective reflectivity is composed of the coupling efficiency between laser and waveguide and Bragg grating reflectivity. In order for the EC-DBR laser to have reasonable laser threshold currents comparable to a single internal cavity laser diode the R_{BG-effective} is computed to be ˜22%. This is obtained from the current threshold scaling with gain fill factor and effective front mirror reflectivity

Iₜₕ^{DBR-EC}/Iₜₕ^{LD}˜(L_{EC}/L_{LD})*[Ln(R_{BG-effective})/Ln(R_{FF})].

This effective reflectivity includes round trip coupling loss between laser and waveguide which is 0.7̂2˜0.5. The Bragg Reflector required is then around 45%.

A grating reflectivity around 42% is achieved using a waveguide core grating with index high of 2.1 for TaO and index low of 1.6 for Alumina. This is computed from DBR theory (see “Diode Laser and Photonic Integrated Circuits” by Coldren et al.). The DBR reflectivity is calculated

R˜((1−n_{low}/n_{high})2^{N})/(1+(n_{low}/n_{high})2^{N})²

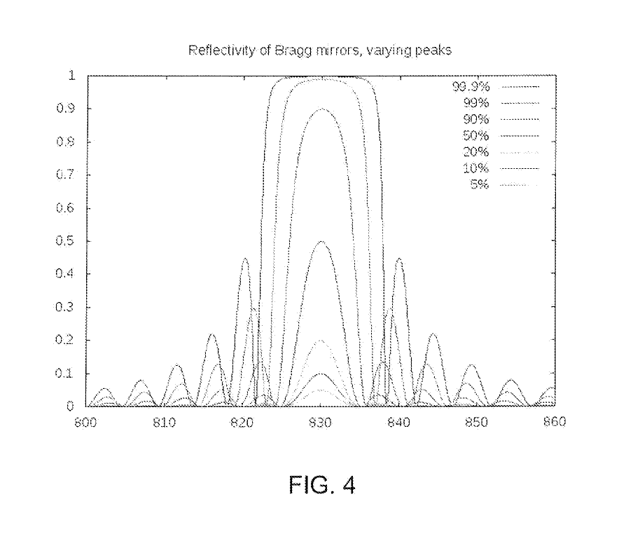

with n_{low} is the low index section, n_{high} is high index section within the grating period and N is the number of periods within the DBR. The grating period is an effective half wave (λ/2. n_{eff}) or with 0.23 μm length and 50% fill factor. The number of periods chosen is 5 to 6, implying 1 to 2 μm grating lengths. The grating fits easily within the slider waveguide optics. Relaxing the index of refraction contrast of the gratings will increase the number of periods and increase the length. An optimum grating design can then be calculated using BeamProp/FullWave and LaserMOD waveguide/grating and laser design software. Calculation using a more accurate grating theory (Coldren) yields the plots of FIG. 4. The 50% reflectivity curve in FIG. 4 shows a spectral width of ˜5 nm. The free spectral range of the EC-DBR longitudinal mode is

Δλ=λ²/2(n_{GaAs}·L_{LD}+n_{Guide}+L_{LD-to-DBR}).

The laser junction temperature may be maintained to within 10 to 20 deg. C. from laser junction temperature to off state. This maintains a laser gain that is roughly flat within self-heating induced gain wavelength excursion.

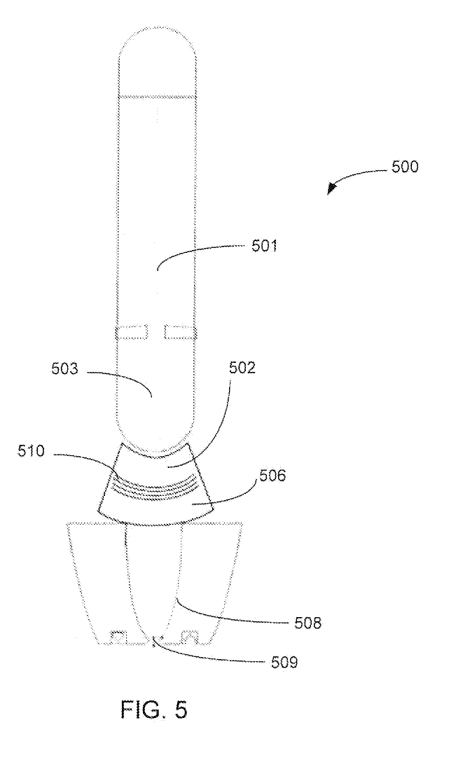

The Bragg grating described herein may be positioned and fabricated in the slider as appropriate to the specific slider design. For example, the Bragg grating may be fabricated in the slider waveguide core before a solid immersion mirror (SIM) that focuses the light to a focal point adjacent the ABS, or the Bragg grating may be fabricated within the channel waveguide prior to the NFT. Example illustrations of Bragg grating placements are provided, but not limited to, those depicted in FIGS. 5-7.

FIG. 5 illustrates an optical path 500 that includes a channel waveguide 501 receives light from a laser diode active region (not shown) at the top. Lines 502 represent expanded light from a beam expander 503 at a bottom end of the waveguide 502. The expanded light 502 passed through a Bragg grating 506 to SIM 508, where it is focused on an NFT 509. In this example configuration, the Bragg grating 506 may be provided with circular grooves 510. Other groove shapes may he possible, e.g., arced, parabolic, hyberbolic.

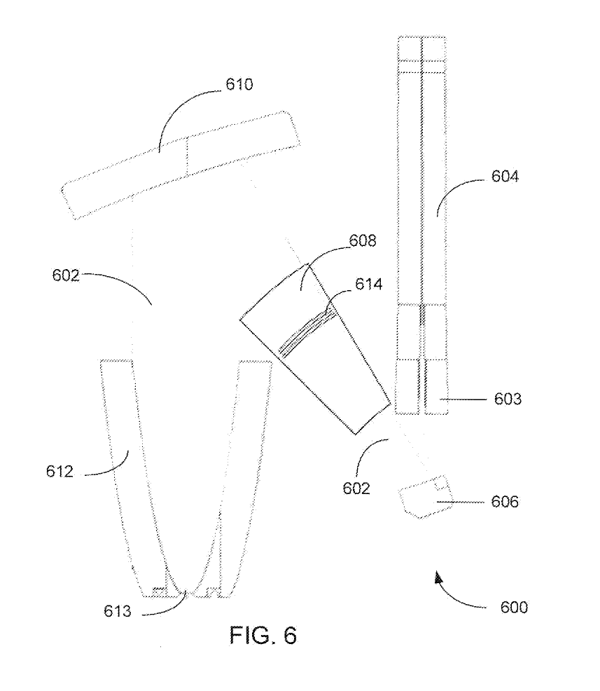

FIG. 6 illustrates an optical path 600 with a waveguide 604 that receives light 602 from a laser diode active region (not shown). The light 602 exits from a beam expander 603 where it is transmitted to a first mirror 606 then reflected and transmitted through the Bragg grating 608 to a second mirror 610 and finally to SIM 612. The SIM 612 focuses the light 602 onto NFT 613. In this example configuration, the Bragg grating 608 may also be provided with circular grooves 614, or grooves with other curved/arced shapes.

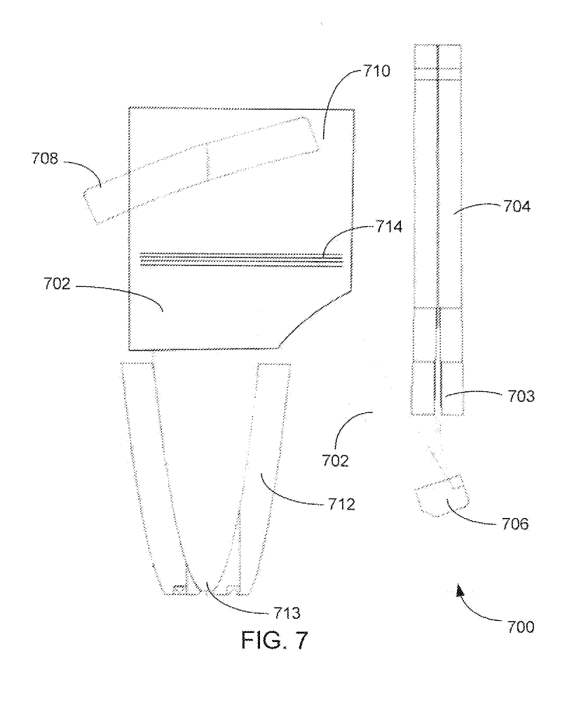

FIG. 7 illustrates an optical path 700 with a waveguide 704 that receives light 702 from a laser diode active region (not shown). The light 702 is transmitted to a first mirror 706 and reflected to a second mirror 708 and then transmitted through the Bragg grating 710 to SIM 712. The SIM 712 focuses the light 702 onto an NFT 713. In this example configuration, the Bragg grating 710 is provided with horizontal grooves 714 and is transparent to off-axis Therefore the light 702 traveling between the first mirror 706 and second mirror 708 is not affected by the Bragg grating 710.

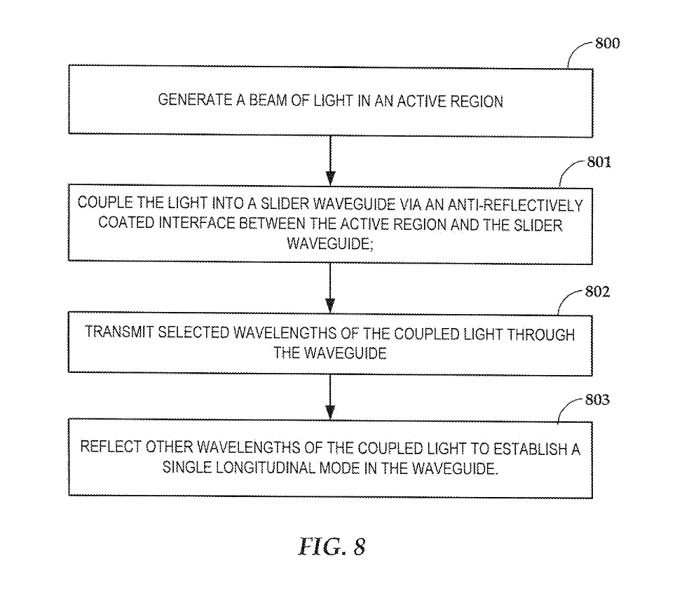

In FIG. 8, a flowchart illustrates a method according to an example embodiment. The method involves generating 800 a beam of light in an active region. The light is coupled 802 into a waveguide of a slider via an anti-reflectively coated interface between the active region and the waveguide. Selected wavelengths of the coupled light are transmitted 803 (e.g., via a Bragg grating) through the waveguide, and other wavelengths of the coupled light are reflected (e.g., via a Bragg grating) to establish a single longitudinal mode in the waveguide.

The Bragg grating external cavity laser diode embodiments of the present disclosure operate to not only remove optical feedback instabilities, e.g., power jumps, but also operate to narrow spectral line width making mode competition mute as the Bragg grating allows for only a single longitudinal node. The embodiments further provide for more efficient light delivery to the disk medium.

Systems, devices or methods disclosed herein may include one or more of the features structures, methods, or combination thereof described herein. For example, a device or method may be implemented to include one or more of the features and/or processes above. It is intended that such device or method need not include all of the features and/or processes described herein, but may be implemented to include selected features and/or processes that provide useful structures and/or functionality.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

Various modifications and additions can be made to the disclosed embodiments discussed above. Accordingly, the scope of the present disclosure should not be limited by the particular embodiments described above, but should be defined only by the claims set forth below and equivalents thereof.

1. An apparatus comprising:
a slider having a waveguide that delivers light to a recording media; and
an external cavity laser comprising:
an active region with a reflective back facet and a front facet externally coupled to the waveguide; and
a Bragg grating within the waveguide, wherein the reflective back facet and the Bragg grating define a single resonator.

2. The apparatus of claim 1, wherein the front facet comprises an anti-reflective coating.

3. The apparatus of claim 2, wherein the waveguide includes an optical coupler adjacent the front facet of the external cavity laser and wherein the optical coupler is coated in an anti-reflective coating.

4. The apparatus of claim 1, wherein the reflective back facet provides at least 95% reflection of light generated by the external cavity laser.

5. The apparatus of claim 1, wherein the Bragg grating transmits a desired wavelength of the light to the recording media and reflects all other light wavelengths into the external cavity.

6. The apparatus of claim 1, wherein the single resonator allows only one longitudinal mode.

7. The apparatus of claim 1, wherein the Bragg grating is located within a cladding layer of the waveguide.

8. An apparatus comprising:
a slider having a waveguide that delivers light to a recording media; and
an external cavity laser comprising:
an active region with a reflective back facet and a front facet externally coupled to the waveguide; and
a Bragg grating within the waveguide, wherein the reflective back facet and the Bragg grating define a single resonator, wherein the Bragg grating is tuned to enable only selected light wavelengths to pass through the Bragg grating and to reflect all other light wavelengths into the external cavity.

9. The apparatus of claim 8, wherein a grating strength of the Bragg grating is adjusted to achieve a desired peak reflectivity.

10. The apparatus of claim 8, wherein the front facet comprises an anti-reflective coating.

11. The apparatus of claim 10, wherein the waveguide includes a coupler interface adjacent the front facet of the external cavity laser and wherein the coupler interface is coated in an anti-reflective coating.

12. The apparatus of claim 8, wherein the reflective back facet provides at least 95% reflection of light generated by the external cavity laser.

13. The apparatus of claim 8, wherein the single resonator allows only one longitudinal mode.

14. The apparatus of claim 8, wherein the Bragg grating is located within a cladding layer of the waveguide.

15. A method comprising:
generating a beam of light in an active region;
coupling the light into a waveguide of a slider via an anti-reflectively coated interface between the active region and the waveguide;
transmitting selected wavelengths of the coupled light through the waveguide; and
reflecting other wavelengths of the coupled light to establish a single longitudinal mode in the waveguide.

16. The method of claim 15, wherein generating a beam of light is performed with a laser diode active region having a front facet that is coated with an anti-reflective coating.

17. The method of claim 15, wherein the transmitting and reflecting is performed by a Bragg grating.

18. The method of claim 17, wherein the waveguide comprises a waveguide core and waveguide cladding, and wherein the Bragg grating is located in the waveguide cladding.

19. The method of claim 17, further comprising expanding the light within the slider wherein the gratings are presented in an arced or circular configuration.

20. The method of claim 19, further comprising reflecting the light between two mirrors within the slider, and wherein the Bragg grating is located between the two mirrors.
